(19) United States
(12) Patent Application Publication
(10) Pub. No.: US 2020/0103295 A1
(43) Pub. Date: Apr. 2, 2020

(54) INTEGRATED STRAIN GAUGES TO EVALUATE PRINTED CIRCUIT BOARD INTEGRITY DURING OPERATION

(71) Applicant: Intel Corporation, Santa Clara, CA (US)

(72) Inventors: Michael A. SCHROEDER, Chandler, AZ (US); Sayed S. SERHAN, Tempe, AZ (US)

(21) Appl. No.: 16/147,549

(22) Filed: Sep. 28, 2018

(51) Int. Cl. G01L 1/22; H01L 23/00; G01K 7/16; G01K 1/14; H05K 1/18

(52) U.S. Cl. CPC G01L 1/2206; H01L 24/17; G01K 7/16; H05K 2201/10151; H05K 1/185; H01L 2924/15311; H01L 2924/3511; G01K 1/14

(57) ABSTRACT

Embodiments herein relate to systems, apparatuses, processing, and techniques related to may generally relate to a printed circuit board (PCB) with one or more strain gauges integrated into the PCB, where the strain gauges are to facilitate an evaluation of PCB integrity during operation of the PCB. The strain gauge may include discrete strain gauges integrated into the PCB at potentially critical stress points within the PCB. The strain gauge may include an electrically conductive daisy chain formation of solder bumps where a change in electrical resistance along the daisy chain formation indicates a strain on the PCB. The strain gauge may include one or more traces included in the PCB, where a change in electrical resistance along the one or more traces is to indicate a strain on the PCB.

### FIELD

Embodiments of the present disclosure generally relate to the field of package assemblies, and in particular package assemblies that monitor board strain to assess package integrity.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Continued reduction in end product size of mobile electronic devices such as smart phones and ultrabooks is a driving force for the development of reduced size systems in package components. In addition, these package components are increasingly implemented in embedded systems such as automotive systems, industrial systems, and the like, which may place additional stresses on the package and related components.

### BRIEF DESCRIPTION OF THE DRAWINGS

FIG. 1 illustrates examples of package warpage, in accordance with embodiments.

FIG. 2 illustrates examples of strain evaluators integrated into corners of an integrated circuit (IC) package, in accordance with embodiments.

FIG. 3 illustrates examples of discrete strain gauges and a temperature sensor integrated into a corner of a ball grid array (BGA), in accordance with embodiments.

FIG. 4 illustrates discrete strain gauges onto a package with traces, in accordance with embodiments.

FIG. 5 illustrates strain evaluators position on a substrate proximate to a package, in accordance with embodiments.

FIG. 6 illustrates an example of discrete strain gauge placement within a PCB, in accordance with embodiments.

FIG. 7 illustrates an example of multiple placements of discreet strain gauges within a PCB around a die, in accordance with embodiments.

FIG. 8 illustrates a system diagram that shows data flow to an evaluator on a PCB, in accordance with embodiments.

FIG. 9 illustrates an example of a process for evaluating PCB integrity, in accordance with embodiments

FIG. 10 is a schematic of a computer system 1000, in accordance with an embodiment of the present invention.

### DETAILED DESCRIPTION

Embodiments of the present disclosure may generally relate to a printed circuit board (PCB) with one or more strain evaluators integrated into the PCB or other substrate board. The strain evaluators are to facilitate an evaluation of PCB integrity during operation of the PCB. In embodiments, PCB strain may be used to monitor IC solder joint integrity. In other embodiments, the strain gauge may include discrete strain gauges (e.g. “off the shelf”) integrated into the PCB at potentially critical stress points within the PCB, which may include corners of a square or rectangular substrate or PCB.

Other embodiments of a strain gauge may include an electrically conductive couplings of non-critical to function (NCTF) solder bumps where a change in electrical resistance along the coupling may indicate a strain on the PCB. In other implementations, any solder bump or electrical pad may be used in the electrical conductive couplings. In embodiments, the electrically conductive couplings may be implemented in a daisy chain configuration. Other embodiments of strain gauges may include one or more specific strain traces included in the PCB, where a change in electrical resistance along the one or more strain traces is to indicate a strain on the PCB. In embodiments, the PCB may be the IC device of substrate or a motherboard PCB. In embodiments, because temperature may also affect the resistance value of a strain gauge, temperature measuring devices may be located proximate to the strain gauges. An analysis may incorporate an electrical resistance measurement from the strain gauge with the temperature proximate to the strain gauge to determine a normalized resistance value. This normalized resistance value may then be compared to PCB strain specifications and tolerance factors to determine whether a critical strain is actually being placed on the PCB and whether that critical strain may compromise package integrity.

(IC packages in embedded systems such as automotive, industrial, and/or military/aerospace/government systems, can be exposed to environmental conditions that may compromise package and solder joint integrity. For functional safety applications, for example in automotive systems, the ability to monitor PCB or substrate board strain may be useful. For example, it may be used to actively monitor package and solder integrity over the life of the system, and to identify potential problems within substrates or packages before the potential problems result in a failure.

In legacy implementations, in particular with thin packages that may be particularly susceptible to applied board strain, specifications released to customers may include board strain limit values for the packages. A user may then simulate and/or otherwise identify specific mechanical boundary condition requirements, and compare those requirements with the board strain limit values in the board specifications. This way, the user may identify whether a particular board would meet their specific mechanical boundary conditions to ensure functional safety with the board.

Such legacy implementations are not effective for boards without associated strain limit values in specifications. In addition, when strain specifications are available, users may or may not use them in their system designs. There would be an advantage to measure package integrity, which may also include solder integrity, in-situ within the PCB, substrate, or board.

Embodiments described herein may include an internal strain gauge that may be designed into a PCB or substrate layout. In embodiments, the internal strain gauge may use NCTF solder bumps, for example on a second level ball grid array (BGA) to form strain gauges by electrically coupling the bumps into daisy chains formations and then measuring the electrical resistance of these formations. In embodiments, the internal strain gauge may also couple with a discrete surface mount resistance temperature detectors (RTD) to account for temperature at the point of the internal strain gauge. In embodiments, the internal strain gauge and RTD may be coupled to a separate IC microcontroller on a PCB or motherboard that may handle the functional safety aspects of one or more PCBs of the system. In embodiments, the IC microcontroller may monitor the strain gauges in real time, make allowances for temperature using the RTD, and then compare the actual measured strain with a specifications strain for the package to actively and regularly measure package integrity in the functioning system.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact. The term “electrically coupled” means that two or more elements are in electrical contact, or that two or more elements are coupled with an electrically conductive material.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the figures, and sizes, thicknesses, or dimensions may be assumed for some embodiments only where specifically indicated or discussed.

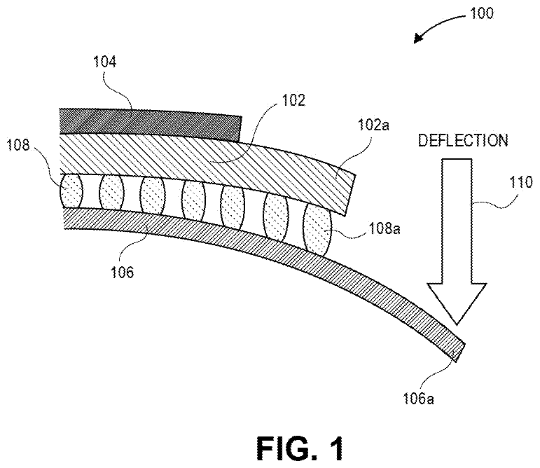

FIG. 1 illustrates examples of package warpage, in accordance with embodiments. Diagram 100 is a package assembly that includes a package substrate 102 coupled with a die 104. The package substrate 102 may include a die 104 that may be coupled with solder bumps or micro bumps (not shown). The package substrate 102 may be coupled to a PCB 106 using a ball grid array (BGA) 108. In embodiments, the PCB 106 may be referred to as a substrate or a board. In embodiments, the BGA 108 may be a plurality of solder balls.

In an original orientation (not shown), the package substrate 102 and the PCB 106 may be roughly planar. However, a deflection force 110 applied to the PCB 106 may cause the PCB 106 to bend to a point 106a that is substantially out of plane. In addition, solder ball 108a that may be near the deflection force 110, may cause a portion of the package substrate 102a to be pulled out of plane as well. In embodiments, the deflection force 110 may result from an incorrect package assembly 100 installation, a material warpage, a board flexure from an outside component (not shown), or a physical shock. In embodiments, the physical shock may come from dropping a system that includes the package assembly 100, or may come from acceleration or deceleration of a system that includes the package assembly 100. In embodiments, deflection and/or warpage may not only be due to mechanical forces, but also due to temperature gradients and/or coefficient of thermal expansion (CTE) mismatches.

As a result, the deflection force 110 may cause package assembly 100 integrity to be compromised by putting a strain on the PCB 106, BGA 108, die 104, and/or package substrate 102. If such a strain is beyond the design limits of the package assembly 100, traces in the PCB 106 and/or package substrate 102 may decouple, or BGA 108 solder points may decouple. This may cause the package assembly 100 to fail.

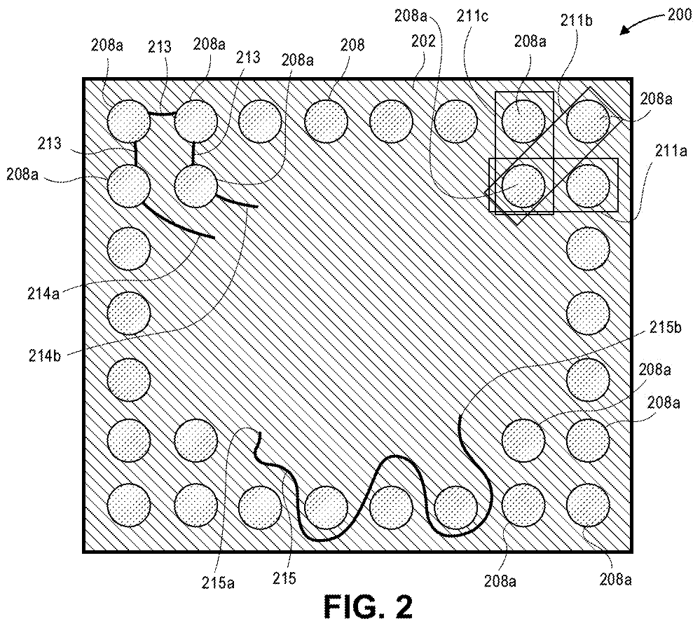

FIG. 2 illustrates examples of strain evaluators integrated into corners of an IC package, in accordance with embodiments. Diagram 200 shows a package substrate 202, which may be similar to package substrate 102 of FIG. 1, with BGA 208, which may be similar to BGA 108 of FIG. 1. In embodiments, PCB 202 may also be similar to the connect side of die 104 where it may connect with package substrate 102 of FIG. 1.

The BGA 208 may include one or more NCTF solder bumps 208a that may not be electrically coupled to either the package substrate 202, die 104, or the PCB 106, but may be added to enhance the structural integrity of the physical connection between package substrate 202 and PCB 106 of FIG. 1.

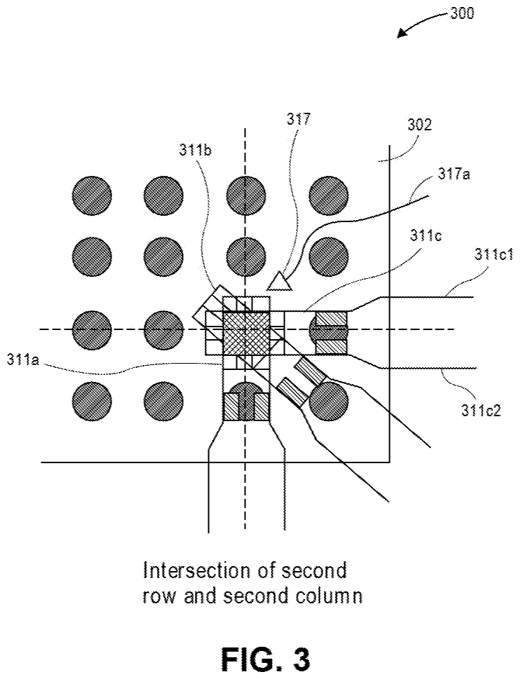

In embodiments, multiple discrete strain gauges may be placed in a rosette orientation as shown in a first orientation 211a, a second orientation 211b, and a third orientation 211c between two NCTF solder balls 208a. In embodiments, the discrete strain gauges may be applied on the package substrate 202 or within layers (not shown) of the package substrate 202. As discussed further with respect to FIG. 3, the discrete strain gauges may indicate a change of an electrical resistance value when two solder balls 208a change distances due to a package substrate deflection such as deflection 110 of FIG. 1. In embodiments, discrete strain gauges may be placed in any location on package substrate 102 of FIG. 1.

In embodiments, a plurality of NCTF solder bumps 208a may be electrically conductively coupled in a chain 213, which may also be referred to as a “series” or a “daisy chain.” The chain 213 may be electrically coupled with two electrical leads 214a, 214b across which an electrical resistance value may be measured. In embodiments, a deflection to solder bumps 208a, for example due to a package substrate deflection such as deflection 110 of FIG. 1, may cause solder bumps 208a to change electrical conductivity properties. This may be due to changes in integrity of the solder bumps 208a along the chain 213, and thus result in a change in the measured electrical resistance value of the chain 213.

In embodiments, a strain trace 215 may be placed in various locations within package substrate 202 to identify a strain on the package substrate 202. The effect of a strain on a package substrate 202 proximate to the strain trace 215, may result in a change of electrical resistance of the strain trace 215. Electrical leads 215a, 215b may be used to measure electrical conductivity properties of the strain trace 215. In embodiments, a strain trace 215 may be implemented by copper traces within layers of the package substrate 202, and integrated as a part of the IC package substrate 202 design.

One or more of the above described embodiments may be used to identify package substrate 202 or BGA 208 integrity indirectly by measuring strain on the package substrate 202 or board. Strain may be identified by changes of the distance between two points within the package substrate 202, which in turn may be identified by changes in electrical resistance values in the strain gauges 211a, 211b, 211c, 213, 215 within the substrate 202.

FIG. 3 illustrates examples of discrete strain gauges and a temperature sensor integrated into a corner of a ball grid array (BGA), in accordance with embodiments. Diagram 300 shows a close-up example of a corner of diagram 200 of FIG. 2. Package substrate 302, which may also be referred to as a board or a PCB, may be similar to package substrate 202 of FIG. 2. Discrete strain gauges 311a, 311b, 311c may be similar to discrete strain gauges 211a, 211b, 211c of FIG. 2. In embodiments, the discrete strain gauges 311a, 311b, 311c may be adhered to the package substrate 302, or may be adhered to a layer (not shown) of the package substrate 302.

In embodiments, the discrete strain gauges 311a, 311b, 311c may be commonly available, such as those manufactured by Vishay Micro-Measurements®, Kyowa®, or NMB®. For further details on discrete strain gauges, see Intel® Manufacturing Enabling Guide, Intel Strain Measurement Methodology for Circuit Board Assembly—Board Flexure Initiative (BFI) March 2016, https://www.intel.com/content/www/us/en/quality/ch4-board-flexure-initiative-guide.html, which is hereby incorporated by reference in full.

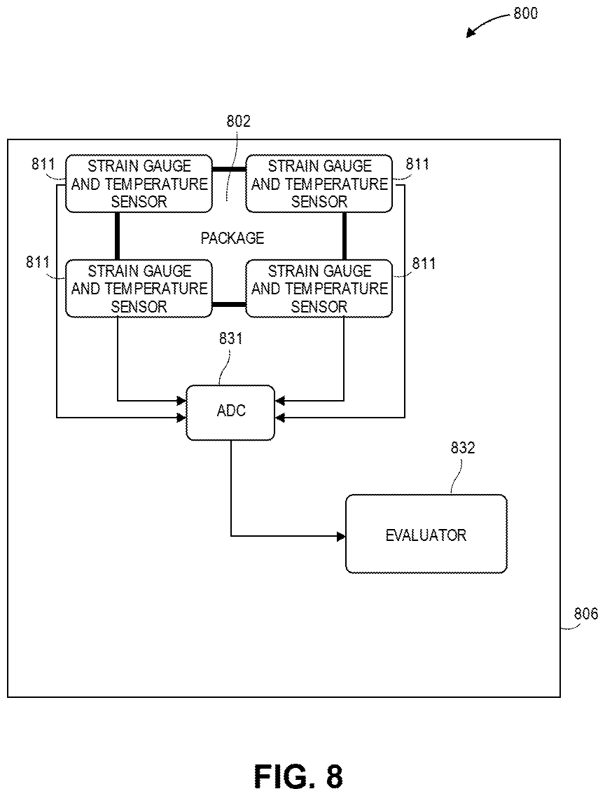

An individual discrete strain gauge, such as discrete strain gauge 311c may include two wire leads 311c1, 311c2, that may lead back to an evaluator circuit (not shown, discussed further with respect to FIG. 8). A measurement across the two wire leads 311c1, 311c2 may be used to determine a value of, or a change in a value of, an electrical resistance value to indicate a potential package substrate 302 strain proximate to the discrete strain gauges 311c.

A temperature sensor 317 may be located proximate to the discrete strain gauge 311c. The temperature sensor 317 may have an electrical lead 317a that provides temperature information to an evaluator (not shown, discussed further with respect to FIG. 8). In embodiments, differences in temperature proximate to an electrical resistance-based strain gauge, such as strain gauge 311c, may also cause changes in electrical resistance values independent of any strain. The temperature sensor 317 may be a RTD. For example, the higher a temperature of an electrically conductive circuit, the greater the electrical resistance value of that circuit.

Therefore, to gain an accurate measurement of board strain from a strain gauge, a temperature proximate to the strain gauge may be combined with an electrical resistance value reported by the strain gauge to produce a determined measurement.

In embodiments, positioning of the strain gauge, such as discrete strain gauges 311a, 311b, 311c, may be most effective in a corner of a substrate package 302 due to corners of a package, or PCB, typically showing the greatest levels of strain.

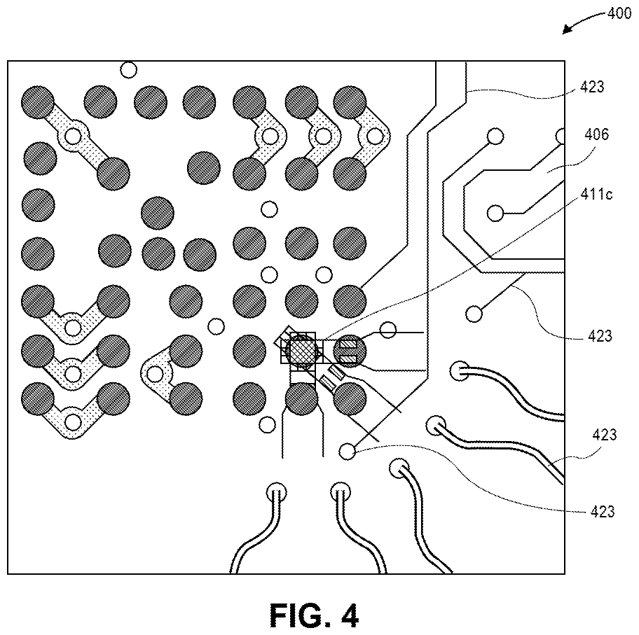

FIG. 4 illustrates discrete strain gauges onto a package with traces, in accordance with embodiments. Diagram 400 shows an expanded view of diagram 300 that includes traces 423 on a PCB 406 that may be used to route signals from the temperature sensor, such as temperature sensor 317 of FIG. 3, or of discrete strain gauge 411c, which may be similar to discrete strain gauge 311c of FIG. 3.

Various traces 423 on the PCB 406 may be electrically coupled with temperature sensor lead 317a, discrete strain gauge leads 311c1, 311c2, or other strain gauges as described above with respect to FIGS. 1-3. The traces 423 may be used to route signals to an evaluator (not shown, discussed further with respect to FIG. 8) that may be located on the PCB 406.

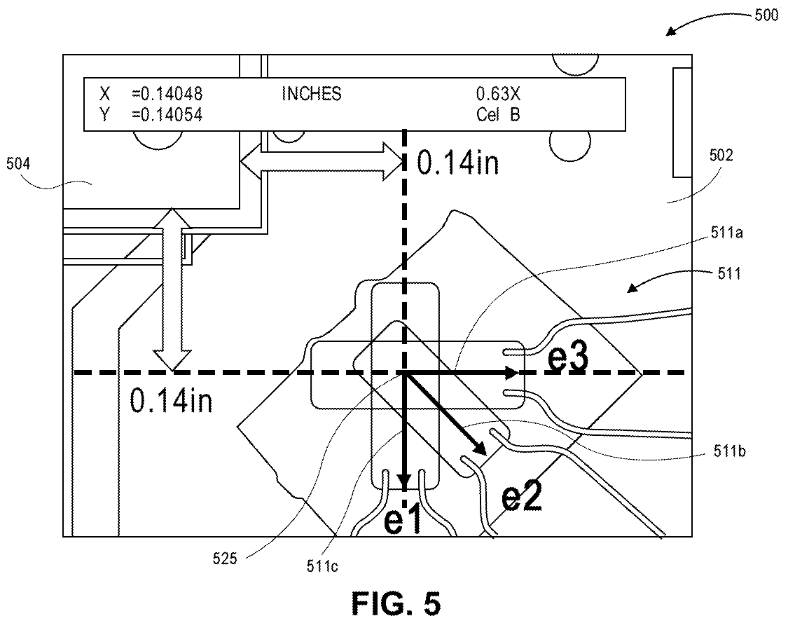

FIG. 5 illustrates strain evaluators position on a substrate proximate to a package, in accordance with embodiments. Diagram 500 shows an image of the set of discrete strain gauges 511a, 511b, 511c that may be similar to strain gauges 311a, 311b, 311c of FIG. 3. The strain gauges 511a, 511b, 511c are positioned on a package substrate 502, which may be similar to package substrate 102 of FIG. 1 within vertical and horizontal tolerances 0.14 inches of a die 504, which may be similar to die 104 of FIG. 1. In embodiments, the strain gauges 511a, 511b, 511c may be oriented in a rosette pattern 511 and intersecting at a common point 525. In this way, strain can be measured in an ex-white plane and not just in a single direction.

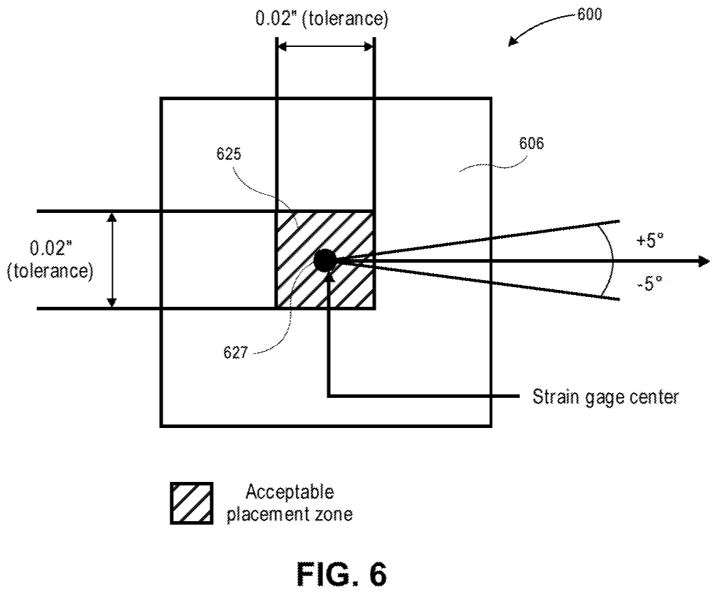

FIG. 6 illustrates an example of discrete strain gauge placement within a PCB, in accordance with embodiments. Diagram 600 shows the position of a discrete strain gauge placement area 625 given a particular point 627 which represents a common point of a rosette discrete strain gauge arrangement, which may be similar to common point 525 of FIG. 5, on the substrate 606, which in turn may be similar to substrate 106 of FIG. 1. In this example, the tolerances of the strain gauge placement with respect to the particular point 627 may be 0.02 inches in a horizontal or vertical direction.

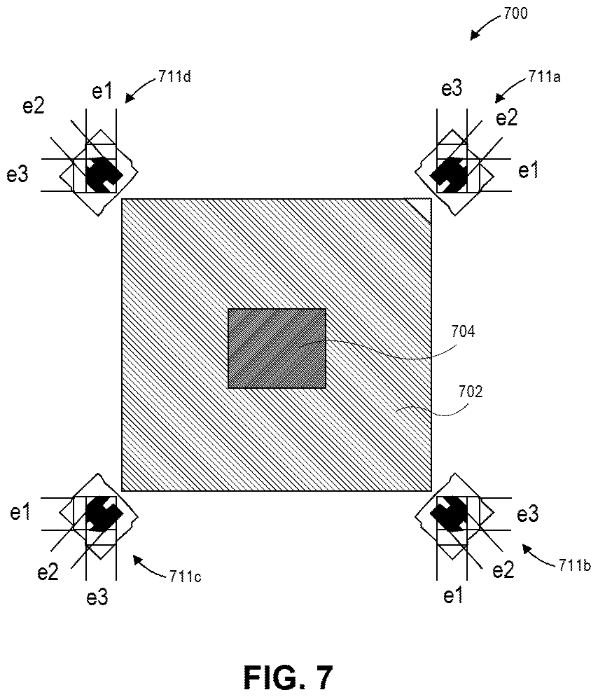

FIG. 7 illustrates an example of multiple placements of discreet strain gauges within a PCB around a die, in accordance with embodiments. Diagram 700 shows a die 704, which may be similar to die 104 of FIG. 1, that is attached to a package substrate 702, which may be similar to package substrate 102 of FIG. 1. Discrete strain gauges, such as discrete strain gauge 311c of FIG. 3, may be oriented in a rosette pattern, such as rosette pattern 511 of FIG. 5, at each corner of the package substrate 702. In embodiments, these rosette patterns 711a, 711b, 711c, 711d may be integrated into the package substrate 702, or may be integrated into the PCB (not shown), such as PCB 106 of FIG. 1, to which the package substrate 702 may be attached. In embodiments, this arrangement may provide accurate strain information with respect to package substrate 702 at corner areas that may be the most susceptible to strain.

FIG. 8 illustrates a system diagram that shows data flow to an evaluator on a PCB, in accordance with embodiments. Diagram 800 shows a PCB 806, which may be similar to PCB 106 of FIG. 1, that may be coupled with a substrate package 802, which may be similar to substrate package 102 of FIG. 1. The package 802 and/or the PCB 806 may include one or more strain gauges and temperature sensors 811. In embodiments, strain gauges may include discrete strain gauges 211a, 211b, 211c of FIG. 2, including discrete strain gauges 511 of FIG. 5 that may be in a rosette pattern. Strain gauges may also include NCTF solder bumps 208a that may be electrically conductive and coupled in a chain 213 as described in FIG. 2. Strain gauges may also include strain traces, such as strain trace 215 of FIG. 2. Each of these strain gauge embodiments may be integrated into a substrate package 802 or the PCB 806.

In embodiments, temperature sensors may include temperature sensor 317 that may be positioned in close proximity to a strain gauge such strain gauge 311c of FIG. 3. In embodiments, temperature sensors may include RTDs.

In embodiments, the output of the strain gauges, such as wire leads 311c1, 311c2, or the output of temperature sensors, such as wire lead 317 of FIG. 3, may be electrically coupled to an evaluator 832. The evaluator 832 may receive information from the various strain gauges and temperature sensors and may determine whether a reported strain gauge value indicates an integrity problem with the package 802 or PCB 806. In embodiments, the wire leads from the strain gauges and temperature sensors may be electrically coupled to one or more traces, such as traces 423 of FIG. 4, that in turn may be electrically coupled to the evaluator 832. In embodiments, the information from the strain gauges and temperature sensors may be in analog form, and may require an analog to digital converter (ADC) 831 to convert the information to a digital form. This digital information may then be sent to the evaluator 832 for digital processing.

In embodiments, the evaluator 832 may be located in a separate IC die or package that may handle other system related package integrity issues. In embodiments, the evaluator 832 may also do system checks, provide error handling, and perform other system integrity related issues related to the PCB 806 and components coupled with it. In embodiments, the evaluator 832 may include package specification information related to various components, including points, such as point 525 of FIG. 5, at which a strain gauges may be embedded. This specification information may include maximum tolerances for strains at that point that may be compared to a measured strain for that point to determine whether there is an integrity failure of the board that may require servicing or replacing.

In addition, the evaluator 832 may also include specification information to allow a measured strain to be determined based upon a strain measurement from a strain gauge and a temperature proximate to the strain gauge. Because increased temperatures may increase electrical resistance values within the strain gauge, temperature values, or temperature values above a threshold level, may require the measurements from the strain gauge to be adjusted so that they reflect an actual strain. In embodiments, this information, as well as other information, may be hardwired into the evaluator 832 or kept in evaluator 832 memory that may be periodically upgraded.

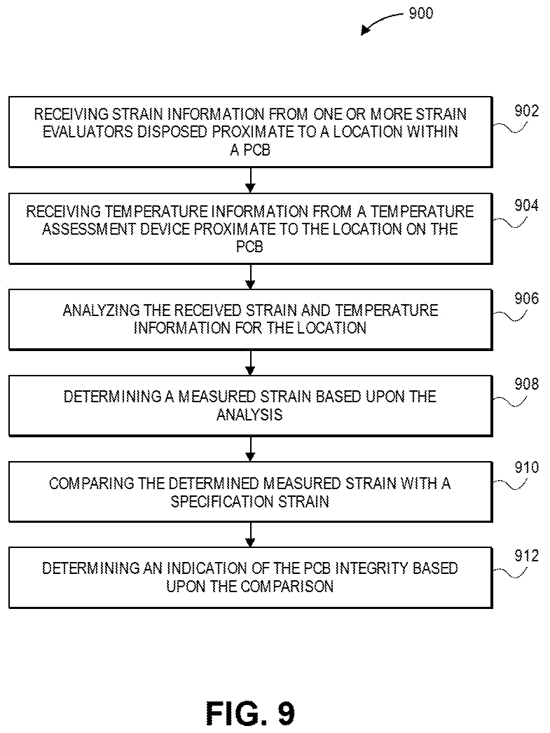

FIG. 9 illustrates an example of a process for evaluating PCB integrity, in accordance with embodiments. In embodiments, process 900 may be performed by one or more of the techniques, processes, or actions described with respect to FIGS. 1-8.

At block 902, the process may include receiving strain information from one or more strain gauges disposed proximate to a location within a PCB. In embodiments, one or more strain gauges may be similar to discrete strain gauges 211a, 211b, 211c, NCTF solder bumps 208a conductively coupled in a chain 213, or strain trace 215 of FIG. 2 that are incorporated into PCB 106 of FIG. 1. In embodiments, the strain gauges may be incorporated into the package substrate 102 of FIG. 1. In embodiments, strain information may include electrical resistance information, or changes in electrical resistance information obtained by a strain gauge.

At block 904, the process may include receiving temperature information from a temperature assessment device proximate to the location in the PCB. In embodiments, a temperature assessment device may be similar to temperature assessment device 317 of FIG. 3. The temperature assessment device may be in close proximity to one or more strain gauges. Temperature information received from the temperature assessment device may be analog-based information to indicate temperature.

At block 906, the process may include analyzing the received strain and temperature information for the location. In embodiments, an evaluator 832 of FIG. 8 may receive the strain and temperature information from respective strain gauges and temperature assessment devices for a particular location for analysis. The analysis may include converting analog signals from strain gauges and temperature assessment devices to digital signals to be processed by the evaluator 832. In embodiments, the evaluator 832 may be an IC chip or package located on a PCB such as PCB 806 of FIG. 8.

Because the strain information may be based on an electrical resistance detected by the strain gauge at a location, and electrical resistance may be also affected by fluctuations in temperature, temperature information of the location may be incorporated with the analysis of the electrical resistance.

At block 908, the process may include determining a measured strain based upon the analysis. In embodiments, the evaluator 832 may incorporate the strain gauge information and the temperature information to normalize or adjust the strain gauge information to determine an actual measured strain at the location. The determined measured strain is to reflect an actual physical strain of the PCB at the location independent of temperature of FIG. 8.

At block 910, the process may include comparing the determined measured strain with a specification strain. In embodiments, the evaluator 832 will compare the determined measured strain with a specification strain of the PCB or the package substrate for the location at which the strain gauge and temperature assessment device may be located of FIG. 8.

At block 912, the process may include determining an indication of the PCB integrity based upon the comparison. In embodiments, the evaluator 832, based on the comparison, made determine that the difference between the determined measured strain and the specification strain is greater than a threshold amount, and may therefore indicate that the PCB integrity has been compromised of FIG. 8. In other embodiments, a plurality of determined measured strains over time for a particular location may be compared, or the measured strains of a plurality of locations over time may be compared, and the results of the comparison may be used to determine whether PCB integrity has been compromised. In embodiments, the evaluator 832 may then send an indication if the PCB integrity has been compromised of FIG. 8.

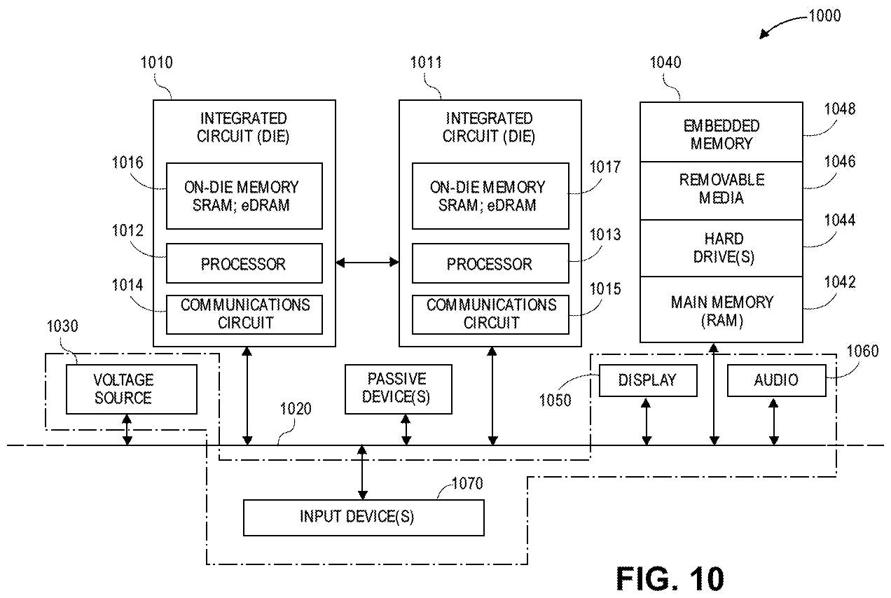

FIG. 10 is a schematic of a computer system 1000, in accordance with an embodiment of the present invention. The computer system 1000 (also referred to as the electronic system 1000) as depicted can embody substrates with in-situ strain gauges, according to any of the several disclosed embodiments and their equivalents as set forth in this disclosure. The computer system 1000 may be a mobile device such as a netbook computer. The computer system 1000 may be a mobile device such as a wireless smart phone. The computer system 1000 may be a desktop computer. The computer system 1000 may be a hand-held reader. The computer system 1000 may be a server system. The computer system 1000 may be a supercomputer or high-performance computing system.

In an embodiment, the electronic system 1000 is a computer system that includes a system bus 1020 to electrically couple the various components of the electronic system 1000. The system bus 1020 is a single bus or any combination of busses according to various embodiments. The electronic system 1000 includes a voltage source 1030 that provides power to the integrated circuit 1010. In some embodiments, the voltage source 1030 supplies current to the integrated circuit 1010 through the system bus 1020.

The integrated circuit 1010 is electrically coupled to the system bus 1020 and includes any circuit, or combination of circuits according to an embodiment. In an embodiment, the integrated circuit 1010 includes a processor 1012 that can be of any type. As used herein, the processor 1012 may mean any type of circuit such as, but not limited to, a microprocessor, a microcontroller, a graphics processor, a digital signal processor, or another processor. In an embodiment, the processor 1012 includes, or is coupled with, a patterned thin film capacitor, as disclosed herein. In an embodiment, SRAM embodiments are found in memory caches of the processor. Other types of circuits that can be included in the integrated circuit 1010 are a custom circuit or an application-specific integrated circuit (ASIC), such as a communications circuit 1014 for use in wireless devices such as cellular telephones, smart phones, pagers, portable computers, two-way radios, and similar electronic systems, or a communications circuit for servers. In an embodiment, the integrated circuit 1010 includes on-die memory 1016 such as static random-access memory (SRAM). In an embodiment, the integrated circuit 410 includes embedded on-die memory 1016 such as embedded dynamic random-access memory (eDRAM).

In an embodiment, the integrated circuit 1010 is complemented with a subsequent integrated circuit 1011. Useful embodiments include a dual processor 1013 and a dual communications circuit 1015 and dual on-die memory 1017 such as SRAM. In an embodiment, the dual integrated circuit 1010 includes embedded on-die memory 1017 such as eDRAM.

In an embodiment, the electronic system 1000 also includes an external memory 1040 that in turn may include one or more memory elements suitable to the particular application, such as a main memory 1042 in the form of RAM, one or more hard drives 1044, and/or one or more drives that handle removable media 1046, such as diskettes, compact disks (CDs), digital variable disks (DVDs), flash memory drives, and other removable media known in the art. The external memory 1040 may also be embedded memory 1048 such as the first die in a die stack, according to an embodiment.

In an embodiment, the electronic system 1000 also includes a display device 1050, an audio output 1060. In an embodiment, the electronic system 1000 includes an input device such as a controller 1070 that may be a keyboard, mouse, trackball, game controller, microphone, voice-recognition device, or any other input device that inputs information into the electronic system 1000. In an embodiment, an input device 1070 is a camera. In an embodiment, an input device 1070 is a digital sound recorder. In an embodiment, an input device 1070 is a camera and a digital sound recorder.

As shown herein, the integrated circuit 1010 can be implemented in a number of different embodiments, including a package substrate having a patterned thin film capacitor, according to any of the several disclosed embodiments and their equivalents, an electronic system, a computer system, one or more methods of fabricating an integrated circuit, and one or more methods of fabricating an electronic assembly that includes a package substrate having a patterned thin film capacitor, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having patterned thin film capacitor embodiments and their equivalents. A foundation substrate may be included, as represented by the dashed line of FIG. 10. Passive devices may also be included, as is also depicted in FIG. 10.

The following paragraphs describe examples of various embodiments.

Example 1 may be an apparatus comprising: a printed circuit board (PCB); one or more strain gauges integrated into the PCB, wherein the strain gauges are to facilitate an evaluation of PCB integrity during operation of the PCB.

Example 2 may be the apparatus of example 1, further comprising one or more traces on the PCB coupled to the one or more strain gauges to transmit information collected from the one or more strain gauges to an analyzer.

Example 3 maybe the apparatus of example 2, further comprising one or more temperature assessment devices on the PCB coupled with at least one of the one or more strain gauges and coupled with at least one of the one or more traces, wherein the temperature assessment devices are to evaluate a temperature proximate to a location of at least one of the one or more strain gauges.

Example 4 maybe the apparatus of example 3, wherein one of the one or more temperature assessment devices is a resistance temperature detector (RTD) device.

Example 5 maybe the apparatus of example 2, wherein a strain gauge further includes one or more discreet strain gauges disposed across a first location and a second location on the PCB to determine a change in distance between the first location and the second location on the PCB; and wherein the one or more discreet strain gauges are electrically coupled with a trace.

Example 6 maybe the apparatus of example 5, wherein the one or more discreet strain gauges are positioned at a corner of the PCB.

Example 7 maybe the apparatus of example 6, wherein the first location and the second location are proximate to a first solder ball and a second solder ball of the PCB.

Example 8 may be the apparatus of example 2, wherein the PCB includes a plurality of non-critical to function (NCTF) bumps; and wherein the strain gauge further includes at least a portion of the plurality of the NCTF bumps that are electrically coupled to each other, wherein a change in an electrical resistance value of the electrically coupled NCTF bumps is to indicate a strain on the PCB.

Example 9 maybe the apparatus of example 8, wherein the plurality of the electrically coupled NCTF bumps are coupled in a daisy chain formation that is electrically coupled to at least one of the one or more traces.

Example 10 maybe the apparatus of example 2, wherein a strain gauge includes one or more strain traces; and wherein the strain gauge is to detect a change in an electrical resistance along the one or more strain traces to indicate a possible strain on the PCB.

Example 11 maybe the apparatus of claim 10, wherein the one or more strain traces are electrically coupled to at least one of the one or more traces.

Example 12 maybe the apparatus of any one of examples 3-11, wherein the analyzer is to use information from the one or more strain gauges and the one or more temperature assessment devices to determine whether the PCB operates within tolerance requirements.

Example 13 may be a package comprising: a PCB; one or more dies coupled to the PCB; one or more strain gauges integrated in the PCB, wherein the strain gauges are to facilitate an evaluation of PCB integrity during operation of the PCB; and one or more traces coupled to at least one of the one or more strain gauges to transmit information collected from the one or more strain gauges to an analyzer.

Example 14 maybe the package of example 13, wherein the one or more traces are coupled to the PCB.

Example 15 maybe the package of example 14, further comprising one or more temperature assessment devices coupled with at least one of the one or more strain gauges and coupled with at least one of the one or more traces, wherein a temperature assessment device is to evaluate a temperature proximate to a location of at least one of the one or more strain gauges.

Example 16 maybe the package of example 15, wherein the analyzer is to use data from the one or more strain evaluators and the one or more temperature assessment devices to determine whether the package operates within tolerance requirements.

Example 17 maybe the package of any one of examples 13-16, wherein the analyzer is located within an IC on the PCB.

Example 18 may be a method comprising: receiving strain information from one or more strain gauges disposed proximate to a location within a PCB; receiving temperature information from a temperature assessment device proximate to the location in the PCB; analyzing the received strain and temperature information for the location; determining a measured strain based upon the analysis; comparing the determined measured strain with a specification strain; and determining an indication of the PCB integrity based upon the comparison.

Example 19 maybe the method of example 18, wherein temperature assessment device is a RTD.

Example 20 maybe the method of example 18, wherein receiving strain information further includes receiving the strain information from a strain gauge that includes a plurality of NCTF bumps coupled in an electrically conductive formation, wherein a change in electrical resistance along the conductive formation is to indicate a strain on the PCB.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a printed circuit board (PCB);
one or more strain gauges integrated into the PCB, wherein the strain gauges are to facilitate an evaluation of PCB integrity during operation of the PCB.

2. The apparatus of claim 1, further comprising one or more traces on the PCB coupled to the one or more strain gauges to transmit information collected from the one or more strain gauges to an analyzer.

3. The apparatus of claim 2, further comprising one or more temperature assessment devices on the PCB coupled with at least one of the one or more strain gauges and coupled with at least one of the one or more traces, wherein the temperature assessment devices are to evaluate a temperature proximate to a location of at least one of the one or more strain gauges.

4. The apparatus of claim 3, wherein one of the one or more temperature assessment devices is a resistance temperature detector (RTD) device.

5. The apparatus of claim 2, wherein a strain gauge further includes one or more discreet strain gauges disposed across a first location and a second location on the PCB to determine a change in distance between the first location and the second location on the PCB; and
wherein the one or more discreet strain gauges are electrically coupled with a trace.

6. The apparatus of claim 5, wherein the one or more discreet strain gauges are positioned at a corner of the PCB.

7. The apparatus of claim 6, wherein the first location and the second location are proximate to a first solder ball and a second solder ball of the PCB.

8. The apparatus of claim 2, wherein the PCB includes a plurality of bumps; and
wherein the strain gauge further includes at least a portion of the plurality of the bumps that are electrically coupled to each other, wherein a change in an electrical resistance value of the electrically coupled bumps is to indicate a strain on the PCB.

9. The apparatus of claim 8, wherein the plurality of the electrically coupled NCTF bumps are coupled in a daisy chain formation that is electrically coupled to at least one of the one or more traces.

10. The apparatus of claim 2, wherein a strain gauge includes one or more strain traces; and
wherein the strain gauge is to detect a change in an electrical resistance along the one or more strain traces to indicate a possible strain on the PCB.

11. The apparatus of claim 10, wherein the one or more strain traces are electrically coupled to at least one of the one or more traces.

12. The apparatus of claim 3, wherein the analyzer is to use information from the one or more strain gauges and the one or more temperature assessment devices to determine whether the PCB operates within tolerance requirements.

13. A package comprising:
a PCB;
one or more dies coupled to the PCB;
one or more strain gauges integrated in the PCB, wherein the strain gauges are to facilitate an evaluation of PCB integrity during operation of the PCB; and
one or more traces coupled to at least one of the one or more strain gauges to transmit information collected from the one or more strain gauges to an analyzer.

14. The package of claim 13, wherein the one or more traces are coupled to the PCB.

15. The package of claim 14, further comprising one or more temperature assessment devices coupled with at least one of the one or more strain gauges and coupled with at least one of the one or more traces, wherein a temperature assessment device is to evaluate a temperature proximate to a location of at least one of the one or more strain gauges.

16. The package of claim 15, wherein the analyzer is to use data from the one or more strain evaluators and the one or more temperature assessment devices to determine whether the package operates within tolerance requirements.

17. The package of claim 13, wherein the analyzer is located within an integrated circuit (IC) on the PCB.

18. A method comprising:
receiving strain information from one or more strain gauges disposed proximate to a location within a PCB;
receiving temperature information from a temperature assessment device proximate to the location in the PCB;
analyzing the received strain and temperature information for the location;
determining a measured strain based upon the analysis;
comparing the determined measured strain with a specification strain; and
determining an indication of the PCB integrity based upon the comparison.

19. The method of claim 18, wherein temperature assessment device is a RTD.

20. The method of claim 18, wherein receiving strain information further includes receiving the strain information from a strain gauge that includes a plurality of bumps coupled in an electrically conductive formation, wherein a change in electrical resistance along the conductive formation is to indicate a strain on the PCB.
